(19) United States
(12) Patent Application Publication
(10) Pub. No.: US 2018/0095265 A1
(43) Pub. Date: Apr. 5, 2018

(54) CURVED DISPLAY PANEL ADHERING DEVICE

(71) Applicant: Shenzhen China Star Optoelectronics Technology Co., Ltd., Shenzhen, Guangdong (CN)

(72) Inventor: Lixuan CHEN, Shenzhen, Guangdong (CN)

(73) Assignee: Shenzhen China Star Optoelectronics Technology Co., Ltd., Shenzhen, Guangdong (CN)

(21) Appl. No.: 15/110,372

(22) PCT Filed: Jun. 8, 2016
(86) PCT No.: PCT/CN2016/085293

§ 371 Date: Jul. 7, 2016

(30) Foreign Application Priority Data
Jan. 26, 2016 (CN) 201610051440.9

(51) Int. Cl. G02B 26/08; G02B 3/00; G02F 1/13; B32B 37/10; G02F 1/1333; H01L 51/56

(52) U.S. Cl. CPC G02B 26/0825; G02B 3/0006; H01L 51/56; B32B 37/10; G02F 1/1333; G02F 1/1303

(57) ABSTRACT

A curved display panel adhering device is disclosed. The device is used for adhering a flexible substrate to a curved glass substrate, wherein, the curved display panel adhering device comprises a control module, a supporting part, multiple suction parts and multiple press-fit heads arranged as a matrix; the supporting part supports the multiple suction parts and the multiple press-fit heads; each of the multiple press-fit heads includes a positioning mechanism and a press-fit contact point located at an end of the positioning mechanism; the suction parts suck and locate the flexible substrate such that the press-fit contact point of the press-fit head abuts and holds the flexible substrate; the control module controls a movement of the supporting part, turning on and off of each suction part and positioning of the positioning mechanism.

### CROSS REFERENCE

The claims of this application have submitted to the State Intellectual Property Office of the People's Republic of China (SIPO) on Jan. 26, 2016, Application No. 201610051440.9. The priority right based on the China application has a title of “Curved display panel adhering device”. The entire contents of the above-mentioned patent application will be incorporated in the present application through citing.

### FIELD OF THE INVENTION

The present invention relates to a liquid crystal manufacturing field, and more particularly to a curved display panel adhering device.

### BACKGROUND OF THE INVENTION

In the manufacturing process of a curved liquid crystal panel, a flexible substrate is required to be adhered to a curved glass substrate. In the conventional art, for a curved glass substrate having a larger curvature radius, a flexible substrate can be stretched or compressed to a flat structure to perform an adhering. Or, using a suction device to fix the flexible substrate and move the flexible substrate above the curved glass substrate and locate precisely, and using a roller to press and fit the flexible substrate from one side of the flexible substrate to the other side. The problem existed in the conventional art is, for a curved glass substrate having a smaller curvature radius, the above adhering method will cause a partial adhering difficult or adhering defect.

### SUMMARY OF THE INVENTION

For the above problem, the purpose of the present invention is to provide a curved display panel adhering device to realize a full adhering for a large curvature radius or a small curvature radius flexible substrate.

The present invention provides a curved display panel adhering device, used for adhering a flexible substrate to a curved glass substrate, wherein, the curved display panel adhering device comprises a control module, a supporting part, multiple suction parts and multiple press-fit heads arranged as a matrix; the supporting part supports the multiple suction parts and the multiple press-fit heads; each of the multiple press-fit heads includes a positioning mechanism and a press-fit contact point located at an end of the positioning mechanism; the suction parts suck and locate the flexible substrate such that the press-fit contact point of the press-fit head abuts and holds the flexible substrate; the control module controls a movement of the supporting part, turning on and off of each suction part and positioning of the positioning mechanism.

Wherein, the suction parts are distributed among the multiple press-fit heads, or located at a periphery of a matrix formed by the multiple press-fit heads; a height between the suction part and the supporting part is lower than a height between the press-fit head and the supporting part.

Wherein, the suction part is located in the press-fit contact point of the press-fit head, and on a surface of the press-fit contact point, a hole connected with the suction part is provided

Wherein, through the control module, selecting H×L press-fit heads arranged as a matrix in the multiple press-fit heads for applying in an adhering process, wherein, H is an integer not less than 1, L is an integer not less than 1.

Wherein, through the control module, selecting H×L press-fit heads arranged as a matrix in the multiple press-fit heads for applying in an adhering process, wherein, H is an integer not less than 1, L is an integer not less than 1.

Wherein, the suction part is communicated with a vacuum equipment.

Wherein, the positioning mechanism is an automatic retractable rod or an automatic linear displacement rod.

Wherein, a surface area of the press-fit contact point is not greater than 1 cm2.

Wherein, a surface area of the press-fit contact point is not greater than 1 cm2.

Wherein, the press-fit contact point can be replaced to be any size and shape.

Wherein, the curved display panel adhering device further comprises a movement part, the supporting part is connected with the movement part, through the control module to control the movement part and change a location of the supporting part.

Wherein, the supporting part is provided with a photosensitive member, and the supporting part performs a precise positioning through the photosensitive member.

The curved display panel adhering device provided by the present invention, adopting multiple press-fit heads to be arranged as a matrix, and adjusting the distribution density of the press-fit heads and the size of the press-fit contact point. Through multiple points to finish an adhering for the curved glass substrate such that the flexible substrate can fully adhere to the curved glass substrate having a large curvature radius or a small curvature radius.

### BRIEF DESCRIPTION OF THE DRAWINGS

In order to more clearly illustrate the technical solution in the present invention or in the prior art, the following will illustrate the figures used for describing the embodiments or the prior art. It is obvious that the following figures are only some embodiments of the present invention. For the person of ordinary skill in the art without creative effort, it can also obtain other figures according to these figures.

FIG. 1 is a top view of a curved display panel adhering device provided by an embodiment of the present invention;

FIG. 2 is a schematic side view of the curved display panel adhering device in an adhering process shown in FIG. 1; and

FIG. 3 is another schematic side view of the curved display panel adhering device in an adhering process shown in FIG. 1.

### DETAILED DESCRIPTION OF THE PREFERRED EMBODIMENT

The following content combines with the drawings and the embodiment for describing the present invention in detail. It is obvious that the following embodiments are only some embodiments of the present invention. For the person of ordinary skill in the art without creative effort, the other embodiments obtained thereby are still covered by the present invention.

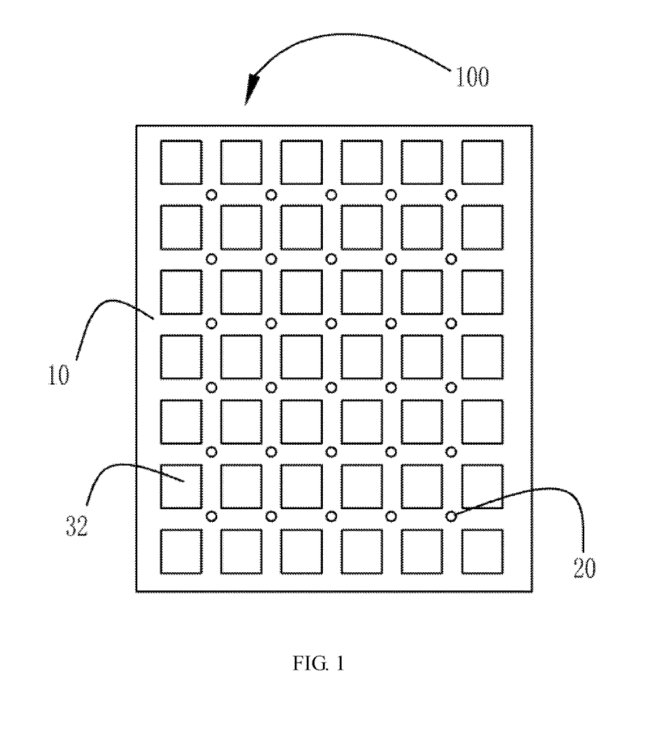

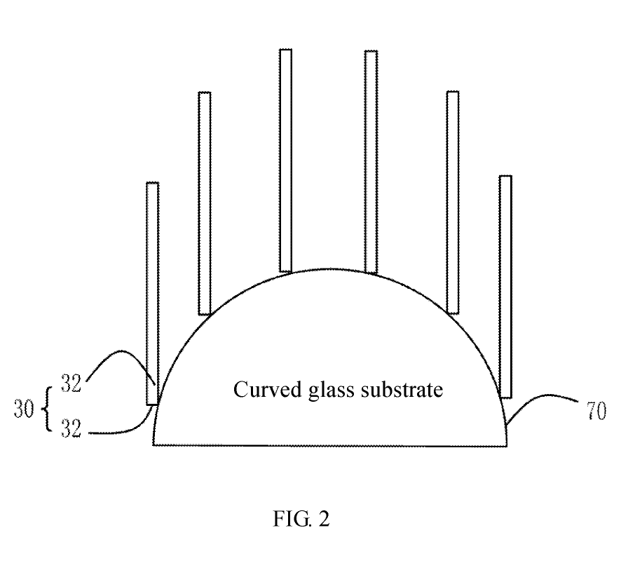

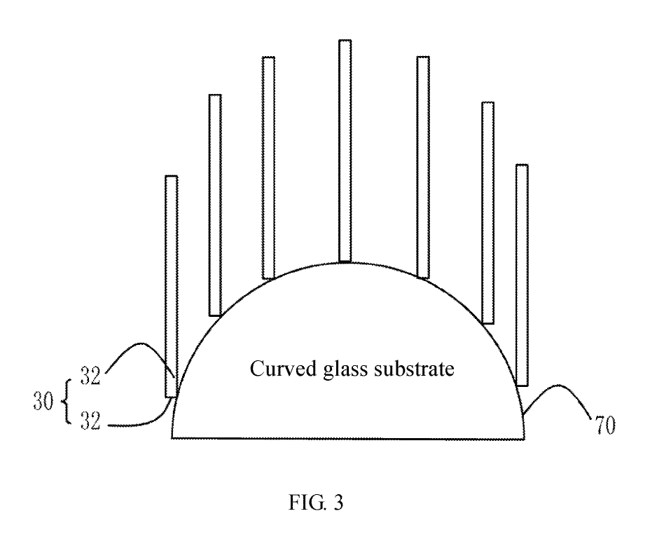

With reference to FIG. 1, FIG. 2 and FIG. 3, a preferred embodiment of the present invention provides a curved display panel adhering device 100. The curved display panel adhering device 100 is used for adhering a flexible substrate 70 to a curved glass substrate. In the present the flexible substrate 70 is a polarizing film. It can be understood that the flexible substrate 70 can be other types of substrates. The curved display panel adhering device 100 includes a control module (not shown in the figure), a movement part (not shown in the figure) and a supporting part 10, suction parts 20 installed on the supporting part 10 and multiple press-fit heads 30 arranged as a matrix. Each of the press-fit heads 30 includes a positioning mechanism 31 and a press-fit contact point 32 located at an end of the positioning mechanism 31.

Wherein, the press-fit contact point 32 is replaceable. That is, according to an actual requirement, a press-fit contact point 32 can be selected for suitable surface dimension and surface shape, and replacing the press-fit contact point 32. Besides, a surface area of the press-fit contact point 32 is not greater than 1 cm2. A shape of each press-fit contact point 32 is a rectangle, a circle, or other shapes, the present invention is not limited. In the present embodiment, the shape of the press-fit contact point 32 is a square. The press-fit contact point 32 has a flexible surface such as a suction cup. According to a curvature radius and a dimension of the curved glass substrate requiring to be adhered with the flexible substrate 70, determining the number of the press-fit heads 30 and the size of the press-fit contact point 32. According to the number of the press-fit heads 30, through the control module, selecting H×L press-fit heads 30 in the multiple press-fit heads 30 for applying in an adhering process. Wherein, H is an integer not less than 1, L is an integer not less than 1. The function of the present embodiment increases the application range of the curved display panel adhering device 100, and increase a generality.

Specifically, for a curved glass substrate having a smaller curvature radius, a surface area of the press-fit contact point 32 is selected to have a smaller value. Beside, under the size of the curved glass substrate is determined, values of H and L are selected to have a larger value. That is, increasing a distribution density of the press-fit heads 30 requiring to be used. Through increasing the distribution density of the press-fit heads 30 and decreasing the surface area of the press-fit contact point 32, the flexible substrate 70 can be fully adhered to the curved glass substrate.

Furthermore, the positioning mechanism 31 is an automatic retractable rod or an automatic linear displacement rod. In the present embodiment, the positioning mechanism 31 is preferably an automatic linear displacement rod. The positioning mechanism 31 includes the displacement rod and a stepper motor. The control module controls the stepper motor to drive the displacement rod to move linearly. The press-fit contact point 32 performs a positioning by the driving of the positioning mechanism 31.

Furthermore, the suction part 20 is communicated with a vacuum equipment. Besides, the control module controls the suction part 20 to turn on or turn off. In the present embodiment, the suction part 20 is a hole communicated with the vacuum equipment. The suction parts 20 are distributed among the multiple press-fit heads 30, or located at a periphery of a matrix formed by the multiple press-fit heads 30. Besides, a height between the suction part 20 and the supporting part 10 is lower than a height between the press-fit head 30 and the supporting part 10 such that when realizing the suction to the curved glass substrate, the press-fit contact point 32 can fully contact with the curved glass substrate. Or, the suction part 20 is located in the press-fit contact point 32 of the press-fit head 30, and on a surface of the press-fit contact point, a hole connected with the suction part 20 is provided. In the present embodiment, the suction part 20 is arranged among the multiple press-fit heads 30, and the height between the suction part 20 and the supporting part 10 is lower than the height between the press-fit head 30 and the supporting part 10.

Furthermore, the supporting part 10 can be a frame or a substrate providing with installation locations. The appearance of the supporting part 10 of the present invention is not limited. The only requirement is to support the suction parts 20 and the press-fit heads 30. The movement part is a movement mechanism controlled by the control module. The supporting part 10 is connected with the movement part (not shown in the figure). Through the control module to control the movement part to move and change the location of the supporting part 10. The supporting part 10 is further provided with a photosensitive member (not shown in the figure).

In the production process, the curved glass substrate is fixed on the rolling platform of the production line. A fixing location of each curved glass substrate is provided with a light-emitting source. Wherein, the rolling platform can be a horizontal platform or a vertical platform. Using a vertical platform to fix the curved glass substrate can reduce the damage caused by own gravity of the curved glass substrate in the adhering process. In the present embodiment, the light-emitting source emits an infrared laser. Through the movement part to move the supporting part 10 to be right above the glass substrate such that photosensitive member can receive the light of the light-emitting source, and the supporting part 10 finish positioning.

Furthermore, using the curved display panel adhering device 100 to perform an adhering includes following steps: (1) according to a size and a curvature radius of a curve glass substrate required to be adhered with a flexible substrate 70, a control module selects values of H and L, and through a surface modeling to determine adhering locations for multiple press-fit heads 30; (2) controlling suction parts 20 to be turned on by the control module, sucking the flexible substrate 70 and making a press-fit contact point 32 of the press-fit head 30 to abut and hold the flexible substrate 70; (3) controlling the movement part to move the supporting part 10 to be right above the curved glass substrate by the control module, and positioning by the photosensitive member; (4) individually controlling the press-fit heads 30 to make the flexible substrate 70 to be adhered to the curved glass substrate according to the adhering locations by the control module. In the adhering process, the suction parts 20 are turned off one by one.

The curved display panel adhering device 100 provided by the present invention, adopting multiple press-fit heads 30 to be arranged as a matrix, and adjusting the distribution density of the press-fit heads 30 and the size of the press-fit contact point 32. Through multiple points to finish an adhering for the curved glass substrate such that the flexible substrate 70 can fully adhere to the curved glass substrate.

The above embodiment does not constitute a limitation of the scope of protection of the present technology solution. Any modifications, equivalent replacements and improvements based on the spirit and principles of the above embodiments should also be included in the protection scope of the present technology solution.

1. A curved display panel adhering device, used for adhering a flexible substrate to a curved glass substrate, wherein, the curved display panel adhering device comprises a control module, a supporting part, multiple suction parts and multiple press-fit heads arranged as a matrix; the supporting part supports the multiple suction parts and the multiple press-fit heads; each of the multiple press-fit heads includes a positioning mechanism and a press-fit contact point located at an end of the positioning mechanism; the suction parts suck and locate the flexible substrate such that the press-fit contact point of the press-fit head abuts and holds the flexible substrate; the control module controls a movement of the supporting part, turning on and off of each suction part and positioning of the positioning mechanism.

2. The curved display panel adhering device according to claim 1, wherein, the suction parts are distributed among the multiple press-fit heads, or located at a periphery of a matrix formed by the multiple press-fit heads; a height between the suction part and the supporting part is lower than a height between the press-fit head and the supporting part.

3. The curved display panel adhering device according to claim 1, wherein, the suction part is located in the press-fit contact point of the press-fit head, and on a surface of the press-fit contact point, a hole connected with the suction part is provided

4. The curved display panel adhering device according to claim 2, wherein, through the control module, selecting H×L press-fit heads arranged as a matrix in the multiple press-fit heads for applying in a adhering process, wherein, H is an integer not less than 1, L is an integer not less than 1.

5. The curved display panel adhering device according to claim 3, wherein, through the control module, selecting H×L press-fit heads arranged as a matrix in the multiple press-fit heads for applying in a adhering process, wherein, H is an integer not less than 1, L is an integer not less than 1.

6. The curved display panel adhering device according to claim 2, wherein, the suction part is communicated with a vacuum equipment.

7. The curved display panel adhering device according to claim 2, wherein, the positioning mechanism is an automatic retractable rod or an automatic linear displacement rod.

8. The curved display panel adhering device according to claim 2, wherein, a surface area of the press-fit contact point is not greater than 1 cm².

9. The curved display panel adhering device according to claim 3, wherein, a surface area of the press-fit contact point is not greater than 1 cm².

10. The curved display panel adhering device according to claim 2, wherein, the press-fit contact point can be replaced to be any size and shape.

11. The curved display panel adhering device according to claim 1, wherein, the curved display panel adhering device further comprises a movement part, the supporting part is connected with the movement part, through the control module to control the movement part and change a location of the supporting part.

12. The curved display panel adhering device according to claim 1, wherein, the supporting part is provided with a photosensitive member, and the supporting part performs a precise positioning through the photosensitive member.

13. The curved display panel adhering device according to claim 3, wherein, the positioning mechanism is an automatic retractable rod or an automatic linear displacement rod.
